(19) United States
(12) Patent Application Publication
(10) Pub. No.: US 2004/0038068 A1
(43) Pub. Date: Feb. 26, 2004

(54) Coated article with polymeric basecoat cured at low temperatures

(76) Inventors: John G. Finch, Livonia, MI (US); Joseph A. Elmer, Lake Orion, MI (US); Daniel E. Ford, Ypsilanti, MI (US); Patrick A. Sullivan, Niwot, CO (US); Robert C. Bishop, Boulder, CO (US)

Correspondence Address: Myron B. Kapustij, Masco Corporation, 21001 Van Born Road, Taylor, MI, 48180, US

(21) Appl. No.: 10/227,891

(22) Filed: Aug. 26, 2002

(51) Int. Cl. C23C 14/14; B32B 15/04; B32B 15/08

(52) U.S. Cl. 428/626; 427/250; 427/255.7; 427/372.2; 427/407.1; 427/255.29; 428/635; 428/632; 428/627; 428/660; 428/698; 428/938

(57) ABSTRACT

A multi-layer coating including a polymeric basecoat layer wherein the polymer of the basecoat layer is cured at subatmospheric pressure.

### FIELD OF THE INVENTION

This invention relates to coated articles with a polymeric basecoat wherein the polymeric basecoat is cured at low or sub-atmospheric pressures.

### BACKGROUND OF THE INVENTION

Coated articles wherein the coating includes a polymeric basecoat layer and a vapor deposited, such as physical vapor deposited, decorative and protective layer comprised of a zirconium compound or titanium compound on the polymeric basecoat layer are known and are disclosed in U.S. Pat. No. 6,168,242. These known polymeric basecoats are cured at ambient pressures. While these ambient pressure cured polymeric basecoats result in decorative and/or protective coatings which are quite good, it would be advantageous if the polymeric basecoat exhibited improved vacuum compatibility for applying the vapor deposited refractory metal compound layers in a vacuum chamber, provided better leveling, minimized color changes, and provided improved mechanical properties. It is an object of the present invention to provide such a polymeric basecoat.

### SUMMARY OF THE INVENTION

In accordance with the instant invention a decorative and/or protective coating is provided on an article. The coating comprises a polymeric basecoat which is cured at low or sub-atmospheric pressures provided on the surface of an article. On the low pressure cured polymeric basecoat layer is then deposited, by vapor deposition such as physical vapor deposition, one or more vapor deposited layers. The vapor deposited layers include the refractory metals and refractory metal compounds.

### BRIEF DESCRIPTION OF THE DRAWINGS

FIG. 1 is a cross-sectional view, not to scale, of a portion of an article having the multi-layer coating of the instant invention;

FIG. 2 is similar to FIG. 1 except that a refractory metal oxide or refractory metal alloy oxide is present as a top layer; and

FIG. 3 is similar to FIG. 2 except that a metal layer is disposed intermediate the polymeric basecoat layer and the stack layer.

### DESCRIPTION OF THE PREFERRED EMBODIMENT

The article or substrate 12 can be comprised of any material onto which a plated layer can be applied, such as plastic, e.g., ABS, polyolefin, polyvinylchloride, and phenolformaldehyde, ceramic, metal or metal alloy. In one embodiment it is comprised of a metal or metallic alloy such as copper, stele, brass, zinc, aluminum, nickel alloys and the like.

In the instant invention a polymeric or resinous layer which is cured under low, below atmospheric, pressure conditions is applied onto the surface of the article. A second layer or series of layers is applied onto the surface of the polymer by vapor deposition. The polymeric layer serves, inter alia, as a basecoat which levels the surface of the article and as a corrosion protective layer.

The polymeric basecoat layer 13 may be comprised of both thermoplastic and thermoset polymeric or resinous material. These polymeric or resinous materials include the well known, conventional and commercially available polycarbonates, epoxy urethanes, polyacrylates, polymethacrylates, nylons, polyesters, polypropylenes, polyepoxies, alkyds and styrene containing polymers such as polystyrene, styrene-acrylonitrile (SAN), styrene-butadiene, acrylonitrile-butadiene-styrene (ABS), and blends and copolymers thereof.

The polycarbonates are described in U.S. Pat. Nos. 4,579,910 and 4,513,037, both of which are incorporated herein by reference.

Nylons are polyamides which can be prepared by the reaction of diamines with dicarboxylic acids. The diamines and dicarboxylic acids which are generally utilized in preparing nylons generally contain from two to about 12 carbon atoms. Nylons can also be prepared by additional polymerization. They are described in “Polyamide Resins”, D. E. Floyd, Reinhold Publishing Corp., new York, 1958, which is incorporated herein by reference.

The polyepoxies are disclosed in “Epoxy Resins”, by H. Lee and K. Nevill, McGraw-Hill, New York, 1957, and in U.S. Pat. Nos. 2,633,458; 4,988,572; 4,680,076; 4,933,429 and 4,999,388, all of which are incorporated herein by reference.

The polyesters are polycondensation products of an aromatic dicarboxylic acid and dihydric alcohol. The aromic dicarboxylic acids include terephthalic acid, isophthalic acid, 4,4′-diphenyl-dicarboxylic acid, 2,6-naphthalenedicarboxylic acid, and the like. Dihydric alcohols include the lower alkane diols with from two to about 10 carbon atoms such as, for example, ethylene glycol, propylene glycol, cyclohexanedimethanol, and the like. Some illustrative non-limiting examples of polyesters include polyethylene terephthalate, polybutylene terephthalate, polyethylene isophthalate, and poly(1,4-cyclohexanedimethylene terephthalate). They are disclosed in U.S. Pat. Nos. 2,645,319; 2,901,466 and 3,047,539, all of which are incorporated herein by reference.

The polyacrylates and polymethacrylates are polymers or resins resulting from the polymerization of one or more acrylates such as, for example, methyl acrylate, ethyl acrylate, butyl acrylate, 2-ethylhexyl acrylate, etc., as well as the methacrylates such as, for instance, methyl methacrylate, ethyl methacrylate, butyl methacrylate, hexyl methacrylate, etc. Copolymers of the above acrylate and methacrylate monomers are also included within the term “polyacrylates or polymethacrylates” as it appears therein. The polymerization of the monomeric acrylates and methacrylates to provide the polyacrylate resins useful in the practice of the invention may be accomplished by any of the well known polymerization techniques.

The styrene-acrylonitrile and acrylonitrile-butadiene-styrene resins and their preparation are disclosed, inter alia, in U.S. Pat. Nos. 2,769,804; 2,989,517; 2,739,142; 3,991,136 and 4,387,179, all of which are incorporated herein by reference.

The alkyd resins are disclosed in “Alkyd Resin Technology”, Patton, Interscience Publishers, NY, N.Y., 1962, and in U.S. Pat. Nos. 3,102,866; 3,228,787 and 4,511,692, all of which are incorporated herein by reference.

The epoxy urethanes and their preparation are disclosed, inter alia, in U.S. Pat. Nos. 3,963,663; 4,705,841; 4,035,274; 4,052,280; 4,066,523; 4,159,233; 4,163,809; 4,229,335 and 3,970,535, all of which are incorporated by reference. Particularly useful epoxy urethanes are those that are electrocoated onto the article. Such electrodepositable epoxy urethanes are described in the afore-mentioned U.S. Pat. Nos. 3,963,663; 4,066,523; 4,159,233; 4,035,274 and 4,070,258.

These polymeric materials may optionally contain the conventional and well known fillers such as mica, talc and glass fibers.

The polymeric basecoat layer 13 may be applied onto the surface of the substrate by any of the well known and conventional methods such as dipping, spraying, brushing and electrodeposition. It is cured under low, i.e., sub-atmospheric, pressure conditions.

The polymeric layer 13 functions, inter alia, to level the surface of the substrate, cover any scratches or imperfections in the surface of the article and provide a smooth and even surface for the deposition of the succeeding layers such as the vapor deposited layers.

The polymeric basecoat layer 13 has a thickness at least effective to level out the surface of the article or substrate and to provide corrosion resistance. Generally, this thickness is at least about 0.12 μm, preferably at least about 2.5 μm, and more preferably at least about 5 μm. The upper thickness range should not exceed about 250 μm.

In some instances, depending on the substrate material and the type of polymeric basecoat, the polymeric basecoat does not adhere sufficiently to the substrate. In such a situation a primer layer is deposited on the substrate to improve the adhesion of the polymeric basecoat to the substrate. The primer layer can be comprised, inter alia, of halogenated polyolefins. The halogenated polyolefins are conventional and well known polymers that are generally commercially available. The preferred halogenated polyolefins are the chlorinated and brominated polyolefins, with the chlorinated polyolefins being more preferred. The halogenated, particularly chlorinated, polyolefins along with methods for their preparation are disclosed, inter alia, in U.S. Pat. Nos. 5,319,032; 5,840,783; 5,385,979; 5,198,485; 5,863,646; 5,489,650 and 4,273,894, all of which are incorporated herein by reference.

The thickness of the primer layer is a thickness effective to improve the adhesion of the polymeric basecoat layer to the substrate. Generally, this thickness is at least about 0.25 μm. The upper thickness is not critical and generally is controlled by secondary considerations such as cost and appearance. Generally an upper thickness of about 125 μm should not be exceeded.

The polymeric basecoat layer is cured at pressure conditions below ambient, i.e., below atmospheric pressures. That is to say, the polymer comprising the basecoat layer is cured at low or sub-atmospheric pressure conditions. These sub-atmospheric pressure conditions are generally below about 10⁻³ torr, preferably below about 10⁻⁴ torr, and more preferably below about 10⁻⁵ torr. The polymeric basecoat is generally cured at elevated temperatures. Generally, these temperatures and the time at which the polymer is kept at these temperatures depend upon the polymer. Generally, these temperatures are above about 100° F., preferably above about 300° F., and the times are from about 20 minutes to about an hour.

In the practice of the instant invention the polymer coated article is inserted into a vacuum chamber, such as for example a vacuum oven, and the vacuum chamber is evacuated to the desired sub-atmospheric pressure. The polymer coated article is kept in the vacuum chamber and heated until the polymer is cured.

In the instant invention the preferred polymers are those which can be electrodeposited on the article. Particularly preferred electrodeposited polymers are the above described epoxy urethanes.

A sandwich or stack layer 32 comprised of alternating layers of refractory metal compound or refractory metal alloy compound 36 and refractory metal or refractory metal alloy 34 is deposited on the sub-atmospheric pressure or vacuum cured polymeric layer 13. The stack layer 32 is deposited by vapor deposition such as physical vapor deposition or chemical vapor deposition. The physical vapor deposition techniques are conventional and well known techniques including cathodic arc evaporation (CAE), reactive cathodic arc evaporation, sputtering, reactive sputtering, and the like. Sputtering techniques and equipment are disclosed, inter alia, in J. Vossen and W. Kern “Thin Film Processes II”, Academic Press, 1991; R. Boxman et al, “Handbook of Vacuum Arc Science and Technology”, Noyes Pub., 1995; and U.S. Pat. Nos. 4,162,954 and 4,591,418, all of which are incorporated herein by reference.

Briefly, in the sputtering deposition process a refractory metal (such as titanium or zirconium) target, which is the cathode, and the substrate are placed in a vacuum chamber. The air in the chamber is evacuated to produce vacuum conditions in the chamber. An inert gas, such as Argon, is introduced into the chamber. The gas particles are ionized and are accelerated to the target to dislodge chromium, titanium or zirconium atoms. The dislodged target material is then typically deposited as a coating film on the substrate.

In cathodic arc evaporation, an electric arc of typically several hundred amperes is struck on the surface of a metal cathode such as zirconium or titanium. The arc vaporizes the cathode material, which then condenses on the substrates forming a coating.

The refractory metals and refractory metal alloys comprising layers 34 include hafnium, tantalum, titanium, zirconium, zirconium-titanium alloy, zirconium-hafnium alloy, and the like, preferably zirconium, titanium or zirconium-titanium alloy, and more preferably zirconium or zirconium-titanium alloy.

The refractory metal compounds and refractory metal alloy compounds comprising layers 36 include, but are not limited to, hafnium compounds, tantalum compounds, titanium compounds, zirconium compounds, and zirconium-titanium alloy compounds, preferably titanium compounds, zirconium compounds, or zirconium-titanium alloy compounds, and more preferably zirconium compounds. These compounds are selected from nitrides, oxides, carbides and carbonitrides, with the nitrides being preferred. Thus, the titanium compound is selected from titanium nitride, titanium oxide, titanium carbide and titanium carbonitride, with titanium nitride being preferred. The zirconium compound is selected from zirconium nitride, zirconium carbide and zirconium carbonitride, with zirconium nitride being preferred.

In one embodiment the refractory metal compounds and refractory metal alloy compounds comprising layers 36 are the refractory metal nitrides and the refractory metal alloy nitrides. When these nitrides, for example zirconium nitride, contain substantially a stoichiometric amount of nitrogen they have a brass color. When these refractory metal nitrides and refractory metal alloy nitrides, for example zirconium nitride, have a low nitrogen content, i.e., substoichiometric, of from about 6 to about 45 atomic percent, preferably from about 8 to about 35 atomic percent, they have a nickel color.

The sandwich or stack layer 32 generally has an average thickness of from about 500 Å to about 1 μm, preferably from about 0.1 μm to about 0.9 μm, and more preferably from about 0.15 μm to about 0.75 μm.

Each of layers 34 and 36 generally has a thickness of at least about 15 Å, preferably at least about 30 Å, and more preferably at least about 75 Å. Generally, layers 34 and 36 should not be thicker than about 0.38 μm, preferably about 0.25 μm, and more preferably about 0.1 μm.

A method of forming the stack layer 32 is by utilizing sputtering or cathodic arc evaporation to deposit a layer 34 of refractory metal such as zirconium or titanium followed by reactive sputtering or reactive cathodic arc evaporation to deposit a layer 36 of refractory metal nitride such as zirconium nitride or titanium nitride.

Preferably the flow rate of nitrogen gas is varied (pulsed) during vapor deposition such as reactive sputtering between zero (no nitrogen gas is introduced) to the introduction of nitrogen at a desired value to form multiple alternating layers of metal 36 and metal nitride 34 in the sandwich layer 32.

The number of alternating layers of refractory metal or refractory metal alloy 34 and refractory metal compound or refractory metal alloy compound layers 36 in sandwich or stack layer 32 is generally at least about 2, preferably at least about 4, and more preferably at least about 6. Generally, the number of alternating layers of refractory metal alloy 34 and refractory metal compound or refractory metal alloy compound 36 in stack layer 32 should generally not exceed about 100, preferably about 50.

Over the stack layer 32 is a color layer 38. The color layer 38 is comprised of refractory metal compound or refractory metal alloy compound such as refractory metal nitride, e.g., zirconium nitride and titanium nitride. Layer 38 has a thickness at least effective to provide a color. Generally, this thickness is at least about 25 Å, and more preferably at least about 500 Å. The upper thickness range is generally not critical and is dependent upon secondary considerations such as cost. Generally a thickness of about 0.75 um, preferably about 0.63 um, and more preferably about 0.5 um should not be exceeded.

The color of the coating will generally be determined by the composition of the vapor deposited color layer 38. Thus, for example, if layer 38 is comprised of a titanium nitride it will have a gold color. If layer 38 is comprised of zirconium nitride containing about a stoichiometric amount of nitrogen it will have a brass color. If layer 38 is comprised of a refractory metal nitride such as zirconium nitride or a refractory metal alloy nitride such as zirconium-titanium alloy nitride wherein the nitride or nitrogen content is less than stoichiometric and generally from about 6 to about 45 atomic percent, preferably from about 8 to about 35 atomic percent it will have a nickel color.

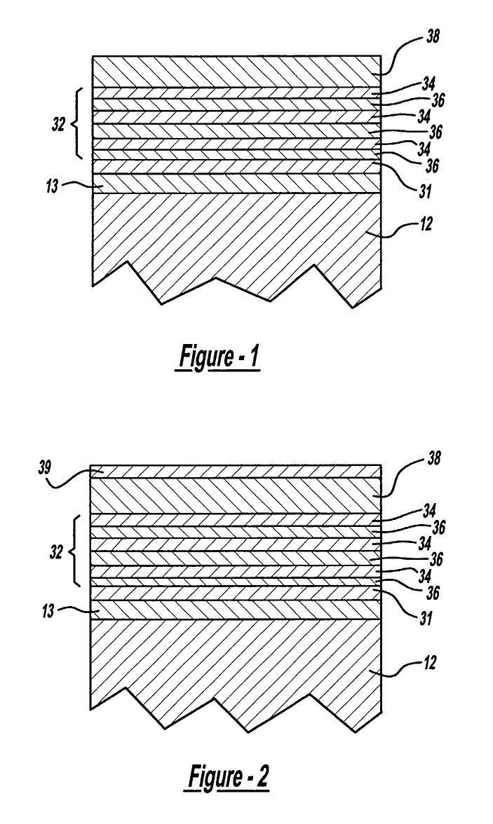

In one embodiment disposed intermediate stack layer 32 and the polymeric basecoat layer 13 is a refractory metal or refractory metal alloy layer 31. The refractory metal layer or refractory metal alloy layer 31 generally functions, inter alia, as a strike layer which improves the adhesion of the stack layer 32 to the polymeric layer. As illustrated in FIGS. 1 and 2, the refractory metal or refractory metal alloy strike layer 31 is generally disposed intermediate the stack layer 32 and the polymeric layer 13. Layer 31 has a thickness which is generally at least effective for layer 31 to function as a strike layer, i.e., improve the adhesion of the stack layer 32 to the polymeric layer 13. Generally, this thickness is at least about 60 Å, preferably at least about 127 Å, and more preferably at least about 250 Å. The upper thickness range is not critical and is generally dependent upon considerations such as cost. Generally, however, layer 31 should not be thicker than about 1.25 μm, preferably about 0.40 um, and more preferably about 0.25 μm.

In a preferred embodiment of the present invention the refractory metal of layer 31 is comprised of titanium or zirconium, preferably zirconium, and the refractory metal alloy is comprised of zirconium-titanium alloy.

In one embodiment of the invention as illustrated in FIG. 2 a layer 39 comprised of the reaction products of a refractory metal or metal alloy, an oxygen containing gas such as oxygen, and nitrogen is deposited onto stack layer 32. The metals that may be employed in the practice of this invention are those which are capable of forming both a metal oxide and a metal nitride under suitable conditions, for example, using a reactive gas comprised of oxygen and nitrogen. The metals may be, for example, tantalum, hafnium, zirconium, zirconium-titanium alloy, and titanium, preferably titanium, zirconium-titanium alloy and zirconium, and more preferably zirconium.

The reaction products of the metal or metal alloy, oxygen and nitrogen are generally comprised of the metal or metal alloy oxide, metal or metal alloy nitride and metal or metal alloy oxy-nitride.

Thus, for example, the reaction products of zirconium, oxygen and nitrogen comprise zirconium oxide, zirconium nitride and zirconium oxy-nitride. These metal oxides and metal nitrides including zirconium oxide and zirconium nitride alloys and their preparation and deposition are conventional and well known, and are disclosed, inter alia, in U.S. Pat. No. 5,367,285, the disclosure of which is incorporated herein by reference.

The layer 39 can be deposited by well known and conventional vapor deposition techniques, including reactive sputtering and cathodic arc evaporation.

In another embodiment instead of layer 39 being comprised of the reaction products of a refractory metal or refractory metal alloy, oxygen and nitrogen, it is comprised of refractory metal oxide or refractory metal alloy oxide. The refractory metal oxides and refractory metal alloy oxides of which layer 39 is comprised include, but are not limited to, hafnium oxide, tantalum oxide, zirconium oxide, titanium oxide, and zirconium-titanium alloy oxide, preferably titanium oxide, zirconium oxide, and zirconium-titanium alloy oxide, and more preferably zirconium oxide. These oxides and their preparation are conventional and well known.

Layer 39 is effective in providing improved chemical, such as acid or base, resistance to the coating. Layer 38 containing (i) the reaction products of refractory metal or refractory metal alloy, oxygen and nitrogen, or (ii) refractory metal oxide or refractory metal alloy oxide generally has a thickness at least effective to provide improved chemical resistance. Generally this thickness is at least about 10 Å, preferably at least about 25 Å, and more preferably at least about 40 521 . Layer 39 should be thin enough so that it does not obscure the color of underlying color layer 38. That is to say layer 39 should be thin enough so that it is non-opaque or substantially transparent. Generally layer 39 should not be thicker than about 500 Å, preferably about 150 Å, and more preferably about 100 Å.

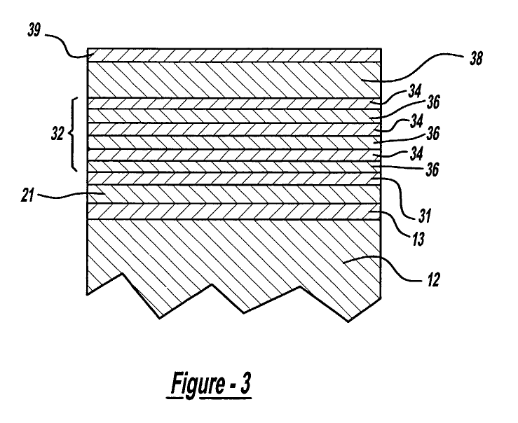

In another embodiment of the invention, as illustrated in FIG. 3, intermediate the vacuum cured electrodeposited polymeric layer 13 and the vapor deposited stack layer 32, there are disposed metal or metal alloy layers 21. These layers 21 may be plated onto the polymeric layer 13 as by electroplating or electroless plating, or they may be vacuum deposited. These metal or metal alloy layers include, but are not limited to, chromium, tin-nickel alloy, and the like. When layer 21 is comprised of chromium it may be deposited on the polymer layer 13 by conventional and well known chromium electroplating techniques. These techniques along with various chrome plating baths are disclosed in Brassard, “Decorative Electroplating—A Process in Transition”, Metal Finishing, pp. 105-108, June 1988; Zaki, “Chromium Plating”, PF Directory, pp. 146-160; and in U.S. Pat. Nos. 4,460,438; 4,234,396; and 4,093,533, all of which are incorporated herein by reference.

Chrome plating baths are well known and commercially available. A typical chrome plating bath contains chromic acid or salts thereof, and catalyst ion such as sulfate or fluoride. The catalyst ions can be provided by sulfuric acid or its salts and fluosilicic acid. The baths may be operated at a temperature of about 112°-116° F. Typically in chrome plating a current density of about 150 amps per square foot, at about 5 to 9 volts is utilized.

The chrome layer generally has a thickness of at least about 0.05 μm, preferably at lest about 0.12 μm, and more preferably at least about 0.2 μm. Generally, the upper range of thickness is not critical and is determined by secondary considerations such as cost. However, the thickness of the chrome layer should generally not exceed about 1.5 μm, preferably about 1.2 μm, and more preferably about 1 μm.

Instead of layer 21 being comprised of chromium it may be comprised of tin-nickel alloy, that is an alloy of nickel and tin. The tin-nickel alloy layer may be deposited on the surface of the substrate by conventional and well known tin-nickel electroplating processes. These processes and plating baths are conventional and well known and are disclosed, inter alia, in U.S. Pat. Nos. 4,033,835; 4,049,508; 3,887,444; 3,772,168 and 3,940,319, all of which are incorporated herein by reference.

The tin-nickel alloy layer is preferably comprised of about 60-70 weight percent tin and about 30-40 weight percent nickel, more preferably about 65% tin and 35% nickel representing the atomic composition SnNi. The plating bath contains sufficient amounts of nickel and tin to provide a tin-nickel alloy of the afore-described composition.

A commercially available tin-nickel plating process is the NiColloy™ process available from ATOTECH, and described in their Technical Information Sheet No: NiColloy, Oct. 30, 1994, incorporated herein by reference.

The thickness of the tin-nickel alloy layer 21 is generally at least about 0.25 μm, preferably at least about 0.5 μm, and more preferably at least about 1.2 μm. The upper thickness range is not critical and is generally dependent on economic considerations. Generally, a thickness of about 50 μm, preferably about 25 μm, and more preferably about 15 μm should not be exceeded.

In order that the invention may be more readily understood, the following example is provided. The example is illustrative and does not limit the invention thereto.

### EXAMPLE

Clean faucets are mounted on racks and lowered into a tank of epoxy urethane paint. A voltage is applied to the parts and slowly ramped to negative 100 V relative to anodes on the sides of the tank, while maintaining the current below 1 ampere. The electric charge transferred (Coulombs) should be about 60% of the total by the time negative 100 V is reached. The total charge transferred to the faucet along with the surface area of the faucet determine the final thickness of the paint film. For a single faucet, about 20 to 30 coulombs of charge transfer are required to obtain a paint thickness of about 0.5 mils. The racks are then lifted out of the paint tank and sequentially dipped into a set of three rinse tanks, each subsequent rinse tank containing less paint and more de-ionized water with a resistivity exceeding 10⁶ ohm-cm.

Following the last rinse, the coated faucets are placed in a vacuum oven, the oven is evacuated to a pressure of 10⁻⁶ torr, the temperature is raised to 560° F., and the epoxy urethane polymer is cured at this pressure and temperature for about 30 minutes.

The cured polymer coated faucets are then placed in a cathodic arc evaporation plating vessel. The vessel is generally a cylindrical enclosure containing a vacuum chamber which is adapted to be evacuated by means of pumps. A source of argon gas is connected to the chamber by an adjustable valve for varying the rate of flow of argon into the chamber. In addition, a source of nitrogen gas is connected to the chamber by an adjustable valve for varying the rate of flow of nitrogen into the chamber.

A cylindrical cathode is mounted in the center of the chamber and connected to negative outputs of a variable D.C. power supply. The positive side of the power supply is connected to the chamber wall. The cathode material comprises zirconium.

The polymer coated faucets are mounted on spindles, 16 of which are mounted on a ring around the outside of the cathode. The entire ring rotates around the cathode while each spindle also rotates around its own axis, resulting in a so-called planetary motion which provides uniform exposure to the cathode for the multiple faucets mounted around each spindle. The ring typically rotates at several rpm, while each spindle makes several revolutions per ring revolution. The spindles are electrically isolated from the chamber and provided with rotatable contacts so that a bias voltage may be applied to the substrates during coating.

The vacuum chamber is evacuated to a pressure of about 5×10⁻³ millibar and heated to about 150° C.

The coated faucets are then subjected to a high-bias arc plasma cleaning in which a (negative) bias voltage of about 500 volts is applied to the coated faucets while an arc of approximately 500 amperes is struck and sustained on the cathode. The duration of the cleaning is approximately five minutes.

Argon gas is introduced at a rate sufficient to maintain a pressure of about 2×10⁻¹ millibars. A layer of zirconium having an average thickness of about 4 millionths (0.000004) of an inch is deposited on the chrome plated faucets during at here minute period. The cathodic arc deposition process comprises applying D.C. power to the cathode to achieve a current flow of about 500 amps, introducing argon gas in to the vessel to maintain the pressure in the vessel at about 2×10⁻¹ millibar and rotating the faucets in a planetary fashion described above.

After the zirconium layer is deposited a stack layer is applied onto the zirconium layer. A flow of nitrogen is introduced into the vacuum chamber periodically at a flow rate of about 5000 sccm while the arc discharge continues at approximate 500 amperes. The nitrogen flow rate is pulsed, that is to say it is changed periodically from about 500 sccm and a flow rate of about zero. The period of nitrogen pulsing is one to two minutes (30 seconds to one minute on, then off). The total time for pulsed deposition is about 15 minutes, resulting in a stack of about 10 to 15 layers of a thickness of about one to about 2.5 Å to about 75 Å for each layer.

After the stack layer is deposited, the nitrogen flow rate is left on at a flow rate of about 500 sccm for a period of time of about 5 to 10 minutes to form the color layer on top of the stack layer. After this zirconium nitride layer is deposited, an additional flow of oxygen of approximately 0.1 standard liters per minute is introduced for a time of thirty seconds to one minute, while maintaining nitrogen and argon flow rates at their previous values. A thin layer of mixed reaction products is formed (zirconium oxy-nitride), with thickness of approximately 50 Å-125 Å. The arc is extinguished at the end of this last deposition period, the vacuum chamber is vented and the coated substrates removed.

While certain embodiments of the invention have been described for purposes of illustration, it is to be understood that there may be various embodiments and modifications within the general scope of the invention.

What is claimed is:

1. An article having on at least a portion of its surface a protective and decorative coating comprising:
a polymeric basecoat wherein said polymeric basecoat is cured at subatmospheric pressure;
stack layer comprising of plurality of layers comprised of refractory metal compound or refractory metal alloy compound layers alternating with layers comprised of refractory metal or refractory metal alloy;
color layer comprised of refractory metal compound or refractory metal alloy compound.

2. The article of claim 1 wherein said refractory metal compound or refractory metal alloy compound is a nitride, carbide, carbonitride or oxide.

3. The article of claim 2 wherein said polymeric basecoat layer is comprised of epoxy-urethane polymer.

4. The article of claim 3 wherein said epoxy-urethane polymer is cured at pressure below about 10⁻³ torr.

5. The article of claim 4 wherein said epoxy-urethane polymer is cured at pressure below about 10⁻⁴ torr.

6. The article of claim 5 wherein said epoxy-urethane polymer is cured at pressure below about 10⁻⁶ torr.

7. The article of claim 4 wherein said epoxy-urethane polymer is cured at elevated temperature.

8. The article of claim 7 wherein said elevated temperature is at least about 100° F.

9. The article of claim 8 wherein said elevated temperature is at least about 300° F.

10. The article of claim 1 wherein said polymeric basecoat is comprised of epoxy-urethane.

11. The article of claim 10 wherein said epoxy-urethane is cured at pressure of below about 10⁻³ torr.

12. The article of claim 4 wherein a metal layer is disposed intermediate said epoxy-urethane polymer and said stack layer.

13. The article of claim 12 wherein said metal layer is chromium.

14. The article of claim 13 wherein an oxide layer is disposed over said color layer.

15. The article of claim 13 wherein said oxide layer is comprised of refractory metal oxide or refractory metal alloy oxide.

16. The article of claim 13 wherein a layer comprised of the reaction products of a refractory metal or refractory metal alloy oxygen and nitrogen is disposed on said color layer.

17. The article of claim 1 wherein an oxide layer is disposed on said color layer.

18. The article of claim 1 wherein said oxide layer is comprised of refractory metal oxide or refractory metal alloy oxide.

19. The article of claim 18 wherein a chromium layer is disposed intermediate said basecoat layer and said stack layer.

20. The article of claim 1 wherein a layer comprised of the reaction products of refractory metal or refractory metal alloy, oxygen and nitrogen is on said color layer.

21. The article of claim 20 wherein a chromium layer is disposed intermediate said basecoat layer and said stack layer.

22. A method of providing a multi-layer protective and decorative coating on at least a portion of an article surface comprising:
applying a polymeric basecoat layer onto said surface and curing said polymeric basecoat at subatmospheric pressure;
applying by physical vapor deposition a stack layer comprised of plurality of layers comprised of refractory metal compound or refractory metal alloy compound layers alternating with refractory metal or refractory metal alloy layers; and
applying by physical vapor deposition on said stack layer color layer comprised of refractory metal compound or refractory metal alloy compound.

23. The method of claim 1 wherein said polymeric basecoat is an epoxy-urethane.

24. The method of claim 23 wherein said subatmospheric pressure is below about 10⁻³ torr.

25. The method of claim 24 wherein said subatmospheric pressure is below about 10⁻⁴ torr.

26. The method of claim 23 wherein a refractory metal oxide layer or refractory metal alloy oxide is applied by physical vapor deposition over said color layer.

27. The method of claim 26 wherein a chromium layer is applied over said epoxy-urethane layer.

28. The method of claim 23 wherein layer comprised of reaction products of refractory metal or refractory metal alloy, oxygen and nitrogen is applied by physical vapor deposition over said color layer.

29. The method of claim 28 wherein a chromium layer is applied over said epoxy-urethane layer.
